(19) United States
(12) Patent Application Publication
(10) Pub. No.: US 2024/0321770 A1
(43) Pub. Date: Sep. 26, 2024

(54) SEMICONDUCTOR PACKAGE INCLUDING SHIELD LAYER AND METHOD OF MANUFACTURING THE SAME

(71) Applicant: SK hynix Inc., Icheon-si Gyeonggi-do (KR)

(72) Inventors: Ki Yong LEE, Icheon-si Gyeonggi-do (KR); Seung Hyun LEE, Icheon-si Gyeonggi-do (KR); Hyoung Min IM, Icheon-si Gyeonggi-do (KR)

(73) Assignee: SK hynix Inc., Icheon-si Gyeonggi-do (KR)

(21) Appl. No.: 18/583,425

(22) Filed: Feb. 21, 2024

(30) Foreign Application Priority Data
Mar. 21, 2023 (KR) 10-2023-0036973
Nov. 8, 2023 (KR) 10-2023-0153868

(51) Int. Cl. H01L 23/552; H01L 23/31; H01L 23/498

(52) U.S. Cl. CPC H01L 23/552; H01L 23/3128; H01L 23/49816; H01L 23/49822

(57) ABSTRACT

A semiconductor package including a shield layer and a method of manufacturing the same. The semiconductor package includes a package substrate, a semiconductor die, an encapsulant layer, and a shield layer. The semiconductor package includes a side that connects a first surface and second surface of the package substrate and includes recesses that are formed along an edge where the second surface and the side meet.

### CROSS-REFERENCE TO RELATED APPLICATIONS

The present application claims priority under 35 U.S.C § 119(a) to Korean Application No. 10-2023-0036973, filed on Mar. 21, 2023, and Korean Application No. 10-2023-0153868, filed on Nov. 8, 2023, in the Korean Intellectual Property Office, which are incorporated herein by reference in their entireties.

### BACKGROUND

The present disclosure relates to a package technology and, particularly, to a semiconductor package including a shield layer and a method of manufacturing the same.

As electronic products are developed in various forms, semiconductor packages that are required for the electronic products are also developed in various forms. A shield layer for preventing electromagnetic interference (EMI) is introduced into the semiconductor packages.

### SUMMARY

In an embodiment, a semiconductor package may include a package substrate, a semiconductor die disposed over the package substrate, an encapsulant layer configured to surround the semiconductor die, and a shield layer configured to surround the encapsulant layer and to cover a side of the package substrate. The package substrate may include a first dielectric layer, a first ground trace disposed on the first dielectric layer, connection patterns configured to connect the first ground trace and the shield layer, and a second dielectric layer configured to surround the first ground trace and the connection patterns. The second dielectric layer may include recesses disposed in the side of the package substrate.

In an embodiment, a semiconductor package may include a package substrate including a side that connects a first surface and a second surface and including recesses at edges where the second surface and the side meet, a semiconductor die disposed in the package substrate, an encapsulant layer configured to encapsulate the semiconductor die, and a shield layer configured to cover the encapsulant layer and the side of the package substrate.

In an embodiment, a method of manufacturing a semiconductor package may include disposing a semiconductor die over a package substrate, forming an encapsulant layer that encapsulates the semiconductor die, disposing the package substrate over a base, forming an initial layer that covers the encapsulant layer and a side of the package substrate and that is disposed on the base, and detaching the package substrate from the base by separating the initial layer into a shield layer that covers the encapsulant layer and the side of the package substrate and into a remainder that remains on the base. The package substrate may include the side that connects a first surface and a second surface and include recesses disposed at edges where the second surface and the side meet.

### BRIEF DESCRIPTION OF THE DRAWINGS

FIG. 1 and FIG. 2 are schematic cross-sectional views illustrating a semiconductor package according to an embodiment.

FIG. 3 and FIG. 4 are diagrams illustrating enlarged views of sections from the semiconductor package illustrated in FIG. 1 according to an embodiment.

FIG. 5 is a schematic plan view illustrating a plane shape of a ground trace of the semiconductor package illustrated in FIG. 1 according to an embodiment.

FIG. 6 is a schematic plan view illustrating a plane shape of a dielectric layer of the semiconductor package illustrated in FIG. 1 according to an embodiment.

FIG. 7 is a schematic plan view illustrating a plane shape of the dielectric layer and plane shape of the ground trace of the semiconductor package illustrated in FIG. 1 according to an embodiment.

FIG. 8 is a schematic plan view illustrating conductive connectors of the semiconductor package illustrated in FIG. 1 according to an embodiment.

FIG. 9 is a schematic plan view illustrating a shield layer and ground trace of the semiconductor package illustrated in FIG. 1 according to an embodiment.

FIG. 10 is a schematic side view illustrating the edges of the shield layer of the semiconductor package illustrated in FIG. 1 according to an embodiment.

FIG. 11 through FIG. 13 are schematic diagrams illustrating the semiconductor package illustrated in FIG. 1 as formed utilizing a method of manufacturing according to an embodiment.

FIG. 14 is a schematic plan view illustrating a conductive burr in a semiconductor package according to an embodiment according to an embodiment.

### DETAILED DESCRIPTION

Terms that are used in the description of the present disclosure are terms selected by taking into consideration functions in proposed embodiments, and the meanings of the terms may differ depending on a user, an operator's intention, or practice in the technical field. The meaning of a term is included in the definition of the term if the term is specifically defined in this specification and may be a meaning that is commonly recognized by those skilled in the art if the term has not been specifically defined.

In the description of the present disclosure, terms, such as “first,” “second,” “bottom,” “top,” a “side,” “surface,” and “lower,” are used to distinguish components from each other for the ease of description and are not intended to limit the components themselves or to indicate specific order or relation. In the description of the present disclosure, terms such as “on or over” or “under or beneath” indicate a relative positional relationship and are not limited to a specific case in which one component comes into direct contact with another component or a third component is located between the two components. The same interpretation may be applied to other expressions that describe a positional relationship between components.

Throughout this specification, the same reference numerals denote the same or similar components. Although not mentioned or described in a corresponding drawing, the same reference numerals or similar reference numerals may be described with reference to another drawing. Furthermore, although a reference numeral is not indicated in a portion of a corresponding drawing, the reference numeral may be described with reference to another drawing. The cross-hatching throughout the figures illustrates corresponding or similar areas between the figures rather than indicating the materials for the areas.

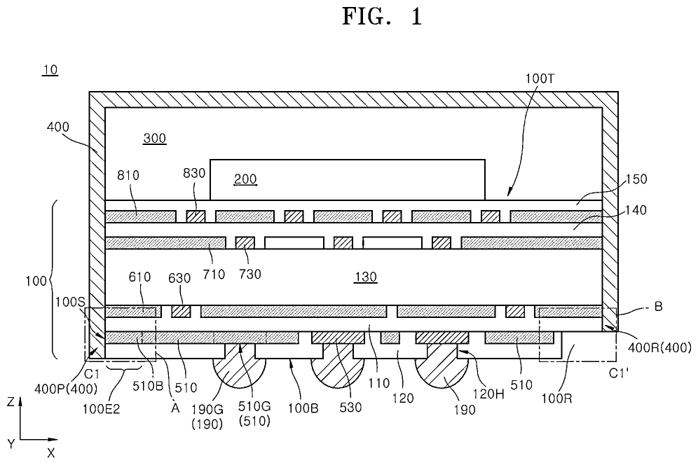

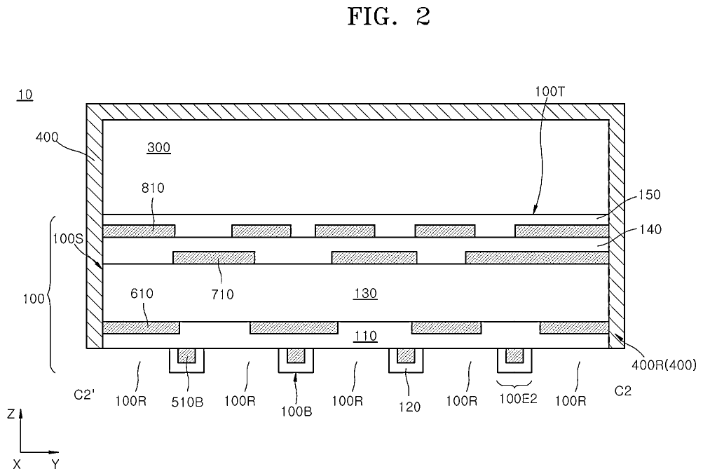

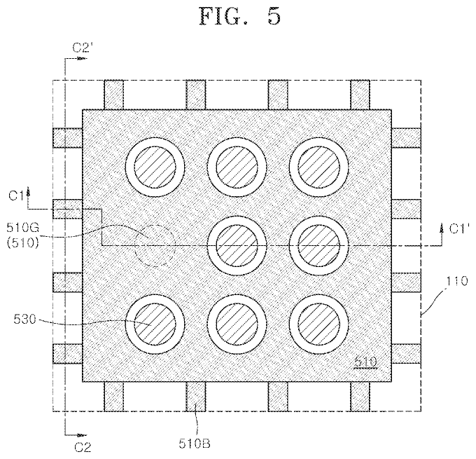

FIG. 1 and FIG. 2 are schematic cross-sectional views illustrating a semiconductor package 10 according to an embodiment. FIG. 1 illustrates a cross-section of the semiconductor package 10 taken along line C1-C1′, for example, in FIG. 5 through FIG. 9 and FIG. 14. FIG. 2 illustrates a cross-section of the semiconductor package 10 taken along line C2-C2′, for example, in FIG. 5 through FIG. 9. FIG. 1 illustrates a cross-section that is cut in an X-axis direction in an X-Y-Z coordinate system. FIG. 2 illustrates a cross-section of that is cut in a Y-axis direction in the X-Y-Z coordinate system. FIG. 2 illustrates a cross-section in which recesses 100R of the semiconductor package 10 are arranged.

Referring to FIG. 1 and FIG. 2, a semiconductor package 10 includes a package substrate 100, a semiconductor die 200, an encapsulant layer 300, and a shield layer 400. FIG. 1 and FIG. 2 illustrate a structure in which one semiconductor die 200 is disposed on the package substrate 100, although a plurality of semiconductor dies 200 may be disposed on the package substrate 100. The plurality of semiconductor dies 200 may be stacked on the package substrate 100. The semiconductor die 200 may include integrated circuits (ICs).

The encapsulant layer 300 may be a protection layer that surrounds the semiconductor die 200. The encapsulant layer 300 may include an encapsulation material such as an epoxy molding compound (EMC). The encapsulant layer 300 may be formed by molding the encapsulation material. The encapsulant layer 300 may extend to cover and protect a top surface 100T of the package substrate 100. The top surface 100T of the package substrate 100 may be a surface that faces the semiconductor die 200. The semiconductor die 200 may be disposed or mounted on the top surface 100T of the package substrate 100 as shown in FIG. 1 and FIG. 2. The encapsulant layer 300 may be formed to cover the semiconductor die 200. In FIG. 1, the encapsulant layer 300 is formed to substantially fully cover the semiconductor die 200, but the present disclosure is not limited thereto. The encapsulant layer 300 may be formed to expose a part of surface of the semiconductor die 200. In FIG. 1, the encapsulant layer 300 does not extend between the semiconductor die 200 and the top surface 100T of the package substrate 100, although the present disclosure is not limited to this embodiment. The semiconductor die 200 may be spaced apart from the top surface 100T of the package substrate 100. The encapsulant layer 300 may extend between the semiconductor die 200 and the top surface 100T of the package substrate 100.

The shield layer 400 may be formed to cover the encapsulant layer 300. The shield layer 400 may extend to cover a side 100S of the package substrate 100 in the example of FIG. 1 and FIG. 2. The shield layer 400 might not extend to a bottom surface 100B of the package substrate 100. The bottom surface 100B of the package substrate 100 may be a surface that is opposite to the top surface 100T. The bottom surface 100B of the package substrate 100 may be a surface that is disposed to be more distant from the semiconductor die 200 than from the top surface 100T. The side 100S of the package substrate 100 includes a surface that connects the top surface 100T and the bottom surface 100B and extends at least partially around an entire perimeter of the package substrate 100 in the X-direction and the Y-direction.

The shield layer 400 may advantageously prevent, reduce, or suppress electromagnetic interference (EMI) between the semiconductor package 10 and an external environment. Because EMI is blocked by the shield layer 400, the semiconductor package 10 may operate without being influenced by EMI. The shield layer 400 may be formed to include a metal material. The metal material may include copper (Cu), nickel (Ni), or stainless steel. The shield layer 400 may include one, two, or more of a copper (Cu) layer, a nickel (Ni) layer, or a stainless steel layer. The shield layer 400 may be formed by sputtering the metal material.

The semiconductor package 10 may further include conductive connectors 190 that are disposed in, disposed on, or attached to the bottom surface 100B of the package substrate 100. The conductive connectors 190 are components that connect the semiconductor package 10 to external parts or other electronic elements. The conductive connectors 190 may include solder balls or conductive bumps.

The package substrate 100 is an interconnection component that connects the semiconductor die 200 to the conductive connectors 190 electrically and through which signals are communicated. The package substrate 100 may be constructed to have a form such as a printed circuit board (PCB), but the present disclosure is not limited to such an implementation. The package substrate 100 includes dielectric layers 110, 120, 130, 140, and 150 and ground traces 510, 610, 710, and 810 in this example. The ground traces 510, 610, 710, and 810 may be electrically connected to the shield layer 400. The ground traces 510, 610, 710, and 810 and the shield layer 400 may constitute an EMI shield structure that surrounds the semiconductor die 200. FIG. 1 and FIG. 2 illustrate a structure in which the four ground traces 510, 610, 710, and 810 are stacked, although the number of ground traces 510, 610, 710, and 810 may be three or less or five or more. The package substrate 100 may include only one ground trace 510. Each ground trace 510, 610, 710, and 810 may cover substantially the majority of the area of the plane in which the ground trace 510, 610, 710, and 810 is disposed.

The package substrate 100 further includes signal traces 530, 630, 730, and 830. The signal traces 530, 630, 730, and 830 provide paths that connect the semiconductor die 200 and the conductive connectors 190 electrically. The signal traces 530, 630, 730, and 830 may be separated from the ground traces 510, 610, 710, and 810 within the package substrate 100. The ground traces 510, 610, 710, and 810 may be disposed between the signal traces 530, 630, 730, and 830. Some of the ground traces 510, 610, 710, and 810 may be disposed to overlap the signal traces 530, 630, 730, and 830 in another layer along the X-axis and/or Y-axis. Through such a structure, signal interference between the signal traces 530, 630, 730, and 830 may be reduced.

The package substrate 100 includes a first dielectric layer 110, a first ground trace 510, a ground connection pattern 510B, and a second dielectric layer 120. The second dielectric layer 120 may be formed to cover the first dielectric layer 110 and to cover the first ground trace 510 and the ground connection pattern 510B under the first dielectric layer 110. The ground connection pattern 510B may be a conductive line that electrically connects the first ground trace 510 to the shield layer 400. The ground connection pattern 510B may include a conductor that extends from the first ground trace 510 and may come into contact with the first ground trace 510.

The first signal traces 530 are separated from the first ground trace 510. The first signal traces 530 may be disposed under the first dielectric layer 110. The conductive connectors 190 are connected to the first signal traces 530. The second dielectric layer 120 includes through-holes 120H that each expose a part of each of the first signal traces 530. Each of the conductive connectors 190 may be bonded to a different one of the first signal traces 530 and may fill the through-hole 120H. The second dielectric layer 120 may be a solder resist layer that electrically isolates the conductive connectors 190. The second dielectric layer 120 may be formed under the first dielectric layer 110 such that the second dielectric layer 120 provides the bottom surface 100B of the package substrate 100. For example, the conductive connectors 190 may comprise solder balls, and the second dielectric layer 120 may comprise a solder resist layer that exposes the solder balls.

The package substrate 100 further includes a third dielectric layer 130, a second ground trace 610, and second signal traces 630 in the example of FIG. 1 and FIG. 2. The third dielectric layer 130 is disposed on or over the first dielectric layer 110. The first dielectric layer 110 may be laminated on the third dielectric layer 130. The third dielectric layer 130 may be a core layer of the package substrate 100. The third dielectric layer 130 may include epoxy resin. The second ground trace 610 and the second signal traces 630 are disposed between the first dielectric layer 110 and the third dielectric layer 130. The second signal traces 630 and the first signal traces 530 may be connected by conductive vias (not illustrated) that penetrate the first dielectric layer 110.

The second ground trace 610 is separated from the second signal traces 630. The second ground trace 610 may be directly connected to the shield layer 400. The second ground trace 610 may overlap the first signal traces 530 along the X-axis and/or Y-axis. The first ground trace 510 overlaps a second signal trace 630 along the X-axis and/or Y-axis in the example of FIG. 1 and FIG. 2. The second ground trace 610, together with the first ground trace 510, may reduce EMI that is generated toward the bottom surface 110B of the package substrate 100.

The package substrate 100 further includes a fourth dielectric layer 140, a third ground trace 710, third signal traces 730, a fifth dielectric layer 150, a fourth ground trace 810, and fourth signal traces 830. The fourth dielectric layer 140 may be laminated to the third dielectric layer 130. The fifth dielectric layer 150 may be laminated to the fourth dielectric layer 140. The third ground trace 710 and the third signal traces 730 may be disposed between the third dielectric layer 130 and the fourth dielectric layer 140. Conductive vias (not illustrated) that substantially penetrate the third dielectric layer 130 may be utilized to connect the third signal traces 730 to the second signal traces 630. The fourth ground trace 810 and the fourth signal traces 830 may be disposed between the fifth dielectric layer 150 and the fourth dielectric layer 140. Conductive vias (not illustrated) that substantially penetrate the fourth dielectric layer 140 may connect the fourth signal traces 830 to the third signal traces 730. The fifth dielectric layer 150 may be a solder resist layer. The semiconductor die 200 may be connected to the fourth signal traces 830 electrically by bonding wires (not illustrated) or conductive bumps (not illustrated).

The ground traces 510, 610, 710, and 810 that are disposed in different layers may be connected by conductive vias (not illustrated). The conductive vias may penetrate the dielectric layers 110, 130, and 140 that isolate the ground traces 510, 610, 710, and 810. The ground traces 510, 610, 710, and 810 may be electrically connected to the semiconductor die 200. The fourth ground trace 810 may be electrically connected to the semiconductor die 200 via bumps and/or bonding wires. The ground traces 510, 610, 710, and 810 may be electrically connected to a ground connector 190G, for example, one of the conductive connectors 190. The ground connector 190G is bonded to a section 510G of the first ground trace 510. The second dielectric layer 120 may be formed to expose the section 510G of the first ground trace 510 to which the ground connector 190G is bonded. The section 510G of the first ground trace 510 to which the ground connector 190G is bonded may be connected to the ground connection pattern 510B and may be electrically connected to the shield layer 400. As described above, the ground traces 510, 610, 710, and 810 and the shield layer 400 may be electrically grounded through the ground connector 190G.

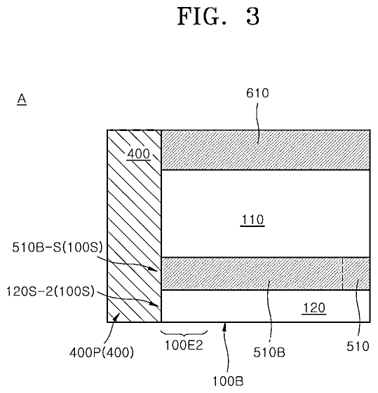

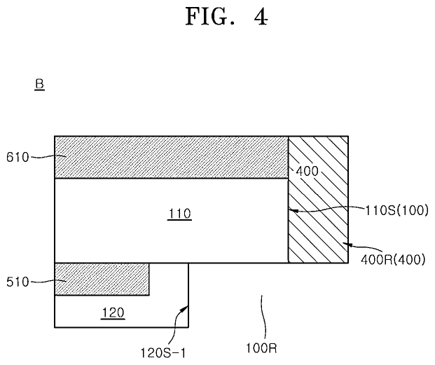

FIG. 3 is a diagram illustrating an enlarged view of section “A” from the semiconductor package 10 illustrated in FIG. 1. FIG. 4 is a diagram illustrating an enlarged view of section “B” from the semiconductor package 10 illustrated in FIG. 1.

Referring to FIG. 1, FIG. 2, FIG. 3, and FIG. 4, the package substrate 100 may include recesses 100R, each disposed at an edge (or periphery) at which the bottom surface 100B and the side 100S meet. Second portions 100E2 of the edges of the package substrate 100 may indicate other edges that neighbor the recesses 100R. Regions in which the recesses 100R are formed may be first portions of the edges of the package substrate 100. The second portion 100E2 of the edges of the package substrate 100 may indicate a portion of an edge where the recess 100R has not been formed. As shown in FIG. 2, the recesses 100R are repeatedly separated from each other along the edges of the package substrate 100. FIG. 2 may illustrate a cross-sectional shape taken along line C2-C2′ that passes through the arranged recesses 100R.

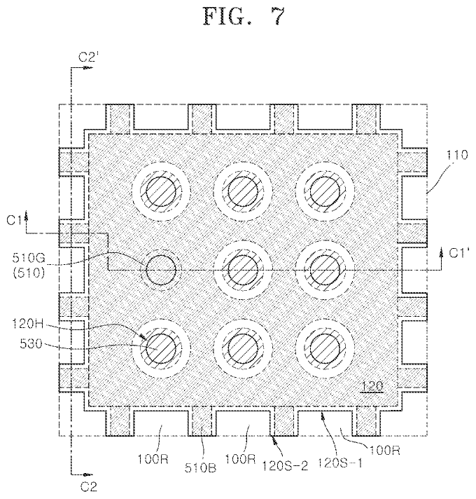

Referring to FIG. 1 and FIG. 4, the recesses 100R may be formed by recessing matter, removing materials, or areas void of substance from the side 100S of the package substrate 100. For example, portions of the second dielectric layer 120 of the package substrate 100 may be selectively removed to form the recesses 100R. The recesses 100R may be formed to expose surface areas of the first dielectric layer 110. A first side part 120S-1 of the second dielectric layer 120, such as shown in FIG. 7, may be spaced apart from the side 100S of the package substrate 100 by a predetermined distance without being aligned with the side 100S of the package substrate 100. The first side part 120S-1 of the second dielectric layer 120 may be adjacent to a side of the recess 100R. The shield layer 400 may cover the side 100S of the package substrate 100 but may expose the recess 100R by extending up to only the side 110S of the first dielectric layer 110. A first end 400R of the shield layer 400 may extend up to only the side 110S of the first dielectric layer 110 as shown in FIG. 4 and might not come into contact with the first side part 120S-1 of the second dielectric layer 120.

Referring to FIG. 1, FIG. 2, and FIG. 3, as with the second portion 100E2 of the edges of the package substrate 100, the second dielectric layer 120 may extend to cover the ground connection pattern 510B. As illustrated in FIG. 2, the recesses 100R are disposed between the ground connection patterns 510B that are covered with the second dielectric layer 120. In other words, the ground connection pattern 510B is isolated from the recesses 100R by the second dielectric layer 120. A side 510B-S of the ground connection pattern 510B may be bonded to the shield layer 400. The shield layer 400 may extend up to a second side 120S-2 of the second dielectric layer 120 while covering the side 100S of the package substrate 100. A second end 400P of the shield layer 400 may extend to cover both the second side 120S-2 of the second dielectric layer 120 and the side 510B-S of the ground connection pattern 510B. The second dielectric layer 120 may cover the ground connection patterns 510B and may protect the ground connection patterns 510B against an external environment by blocking or covering the ground connection patterns 510B. The second dielectric layer 120 may reduce or suppress a failure in which the ground connection patterns 510B is damaged, contaminated, or oxidized by an external environment.

FIG. 5 is a plan view illustrating a plane shape of the first ground trace 510 of the semiconductor package 10 illustrated in FIG. 1. FIG. 1 illustrates a cross-section taken along line C1-C1′ in FIG. 5. FIG. 2 illustrates a cross-section taken along line C2-C2′ of FIG. 5.

Referring to FIG. 1, FIG. 2, and FIG. 5, the first ground trace 510 is separated from the first signal traces 530. The ground connection patterns 510B may be disposed at the edges of the first ground trace 510. The ground connection patterns 510B may be protrusions that protrude from the first ground trace 510. The ground connection patterns 510B may extended from or are enlarged from the first ground trace 510 up to a boundary surface of the package substrate 100. The ground connection patterns 510B and the first ground trace 510 may be formed as single layer. The ground connection patterns 510B may each be formed to have a bar or rectangular shape.

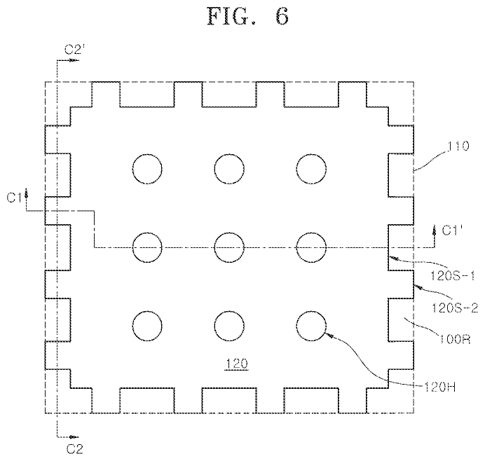

FIG. 6 is a plan view illustrating a plane shape of the second dielectric layer 120 of the semiconductor package 10 illustrated in FIG. 1. FIG. 7 is a plan view illustrating the plane shape of the second dielectric layer 120 and plane shape of the first ground trace 510 of the semiconductor package 10 illustrated in FIG. 1. FIG. 1 illustrates a cross-section taken along line C1-C1′ in FIG. 6 and FIG. 7. FIG. 2 illustrates a cross-section taken along line C2-C2′ of FIG. 6 and FIG. 7.

Referring to FIG. 1, FIG. 2, FIG. 6, and FIG. 7, the second dielectric layer 120 includes the recesses 100R that are separated from each other along the edge of the package substrate 100. The second dielectric layer 120 includes the through holes 120H that expose a part of each of the first signal traces 530 and the section 510G of the first ground trace 510. The second dielectric layer 120 may extend to cover the ground connection patterns 510B. Referring to FIG. 1, FIG. 2, FIG. 3, FIG. 6, and FIG. 7, the second dielectric layer 120 of the package substrate 100 blocks the first ground trace 510 and the connection patterns 510B by covering the ground trace 510 and the connection patterns 510B. The recesses 100R are disposed in the second dielectric layer 120.

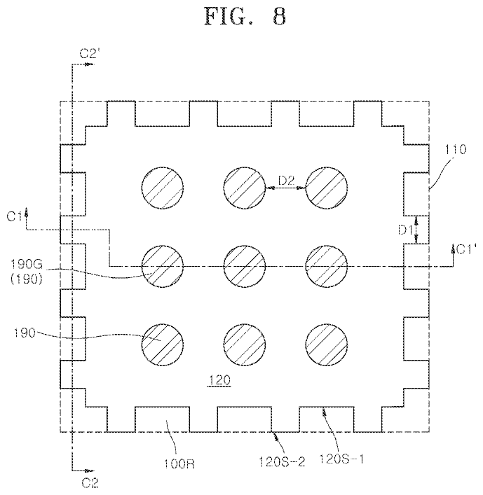

FIG. 8 is a plan view illustrating the conductive connectors 190 of the semiconductor package 10 illustrated in FIG. 1. FIG. 1 illustrates a cross-section taken along line C1-C1′ of FIG. 8. FIG. 2 illustrates a cross-section taken along line C2-C2′ of FIG. 8.

Referring to FIG. 1, FIG. 2, and FIG. 8, the conductive connectors 190 are separated from each other. The recesses 100R of the package substrate 100 may be spaced apart from each other at a distance D1. The distance D1 is narrower than a distance D2, which is the distance between the conductive connectors 190. The distance D1 at which the recesses 100R are spaced apart from each other may be the shortest distance between two recesses 100R that are adjacent to or closest to each other. The distance D2 at which the conductive connectors 190 are spaced apart from each other may be the shortest distance between two conductive connectors 190 that are adjacent to or closest to each other.

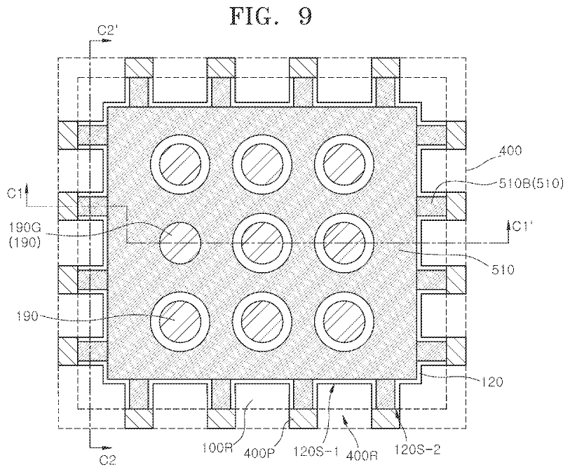

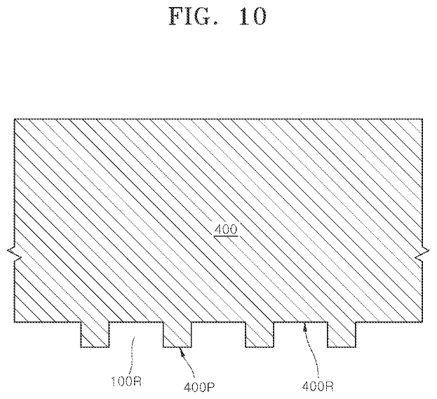

FIG. 9 is a plan view illustrating edges 400R and 400P of the shield layer 400 and first ground trace 510 of the semiconductor package 10 illustrated in FIG. 1. FIG. 10 is a side view illustrating the edges 400R and 400P of the shield layer 400 of the semiconductor package 10 illustrated in FIG. 1. FIG. 10 illustrates a shape of the semiconductor package 10 illustrated in FIG. 2, which is viewed in the X-axis direction. FIG. 1 illustrates a cross-section taken along line C1-C1′ of FIG. 9. FIG. 2 illustrates a cross-section taken along line C2-C2′ of FIG. 9.

Referring to FIG. 1, FIG. 2, FIG. 9, and FIG. 10, the shield layer 400 covers portions of the side 100S between the recesses 100R. The shield layer 400 may include an alternating inward and outward feature that exposes the recesses 100R along the ends or edges 400R and 400P of portions that cover the side 100S of the package substrate 100. Because the first ends 400R and the second ends 400P of the shield layer 400 are alternately disposed along the arrangement of the recesses 100R, the ends or edges 400R and 400P of the shield layer 400 have an inward-outward feature. As illustrated in FIG. 9, the second end 400P of the shield layer 400 is bonded to the ground connection pattern 510B, the second end 400P is electrically connected to the first ground trace 510. Furthermore, the second end 400P of the shield layer 400 is bonded to the second side 120S-2 of the second dielectric layer 120.

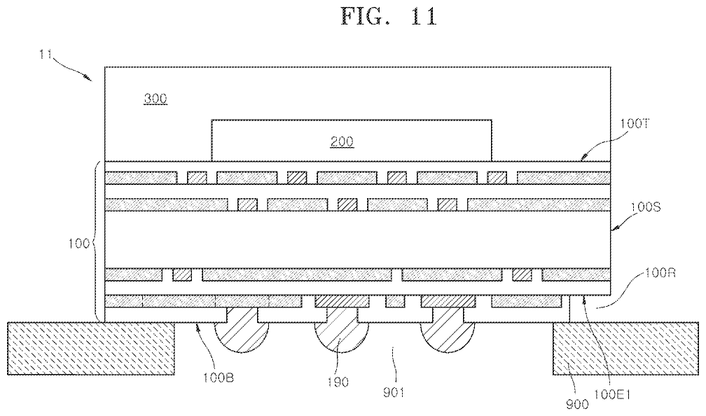

FIG. 11 through FIG. 13 are schematic diagrams illustrating the semiconductor package 10 illustrated in FIG. 1 as formed utilizing a method of manufacturing according to an embodiment. In FIG. 11 through FIG. 13, components that utilize the same reference numerals and/or the same shapes as those in FIG. 1 through FIG. 10 indicate substantially the same components.

Referring to FIG. 11, the semiconductor die 200 is disposed on or over the package substrate 100. The semiconductor die 200 may be mounted on the top surface 100T of the package substrate 100. The package substrate 100 includes the bottom surface 100B opposite to the top surface 100T and the side 100S. The package substrate 100 includes the recesses 100R that are arranged along the edge where the bottom surface 100B and the side 100S meet. The encapsulant layer 300 is formed to surround the semiconductor die 200. The conductive connectors 190 are attached to the package substrate 100. The conductive connectors 190 are disposed on the bottom surface 100B of the package substrate 100 in the example of FIG. 11. As described above, a semiconductor package pre-structure 11 is formed, and the semiconductor package pre-structure 11 may be disposed on a base 900. The semiconductor package pre-structure 11 may be a pre-structure for implementing the semiconductor package 10 illustrated in FIG. 1.

The package substrate 100 is disposed over the base 900 such that portions of the bottom surface 100B of the package substrate 100 come into contact with a part of the surface of the base 900. The base 900 includes a cavity 901 that accommodates the conductive connectors 190 attached to the package substrate 100. The base 900 may be a film to which the package substrate 100 may be attached. The base 900 may be formed as a platform with an adhesive layer (not illustrated) to which the package substrate 100 may be attached.

Some areas of the bottom surface 100B of the package substrate 100 are contact with a surface of the base 900, but while some of the edges of the package substrate 100 are spaced apart from the base 900, without contacting the surface of the base 900, by the recesses 100R of the package substrate 100. Some portions of the side 100S of the package substrate 100 are spaced apart from the base 900 by the recesses 100R. Accordingly, gaps or openings may be provided between the package substrate 100 and the base 900.

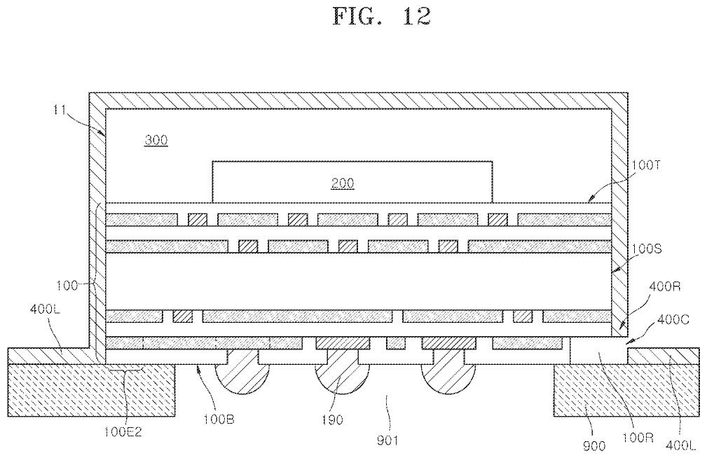

Referring to FIG. 12, an initial layer 400L for the shield layer 400 of FIG. 1 may be formed on the semiconductor package pre-structure 11 and the base 900. The initial layer 400L may extend to cover the encapsulant layer 300 and the side 100S of the package substrate 100 and to further cover some of the surface of the base 900. The initial layer 400L may be formed by sputtering a metal material onto the semiconductor package pre-structure 11. The initial layer 400L may also be formed on the surface of the base 900 because sputtering is simultaneously performed on the semiconductor package pre-structure 11 and the base 900. The initial layer 400L may extend to cover some of the side 100S of the package substrate 100 and to cover some of the surface of the base 900 because the second portion 100E2 of the package substrate 100 is in contact with the surface of the base 900.

Openings 400C in the initial layer 400L are generated at locations adjoining the recesses 100R because the gaps or openings are provided between the package substrate 100 and the base 900. The initial layer 400L may be discontinuous at the openings 400C because the metal materials are not sufficiently sputtered onto the recesses 100R. Accordingly, the first end 400R of the initial layer 400L may be formed to expose the recess 100R.

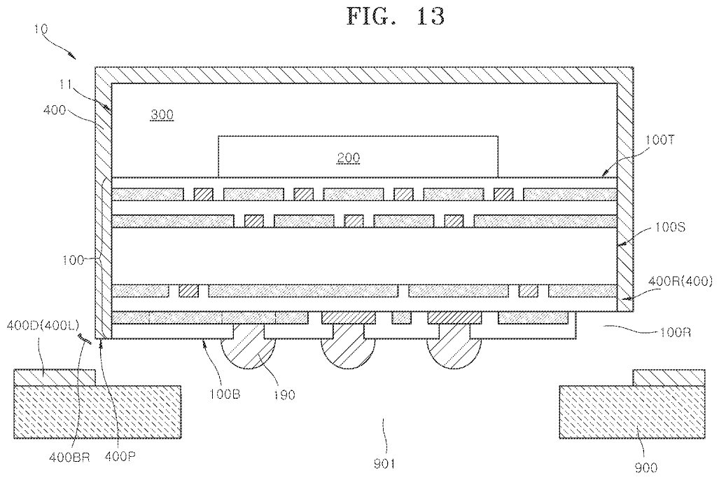

Referring to FIG. 13, the package substrate 100 is detached from the base 900. The shield layer 400 is a part of the initial layer 400L that covers the encapsulant layer 300 and that covers the side 100S of the package substrate 100. The remainder 400D is a part of the initial layer 400L that remains with the base 900 after separation. The initial layer 400L may be separated into the shield layer 400 and the remainder 400D at a location where the side 100S of the package substrate 100 contacts the surface of the base 900.

As the initial layer 400L is separated into the shield layer 400 and the remainder 400D, conductive burrs 400BR may be formed near the second end 400P of the shield layer 400. The conductive burrs 400BR might not result because the openings 400C formed in the initial layer 400L near the recesses 100R are already separated from the initial layer 400L. The occurrence of the conductive burr 400BR may be reduced by forming the recesses 100R.

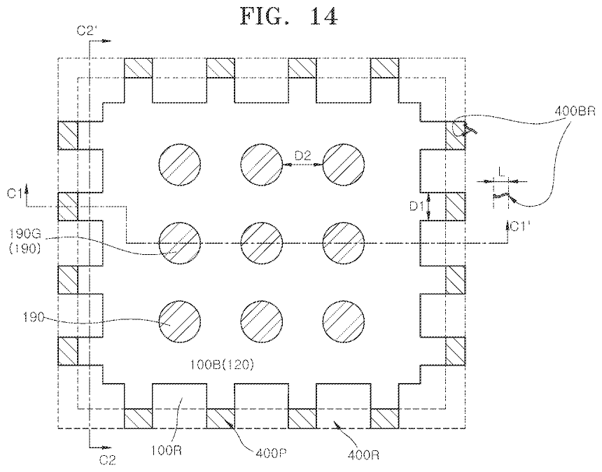

FIG. 14 is a plan view illustrating the conductive burr 400BR of FIG. 13.

Referring to FIG. 13 and FIG. 14, the length L of the conductive burr 400BR may be reduced by limiting the distance D1 between the recesses 100R. The length L of the conductive burr 400BR that occurs may be induced to be smaller than the distance D2 between the conductive connectors 190 when the distance D1 between the recesses 100R is narrower than the distance D2 between the conductive connectors 190. Although some of the conductive burrs 400BR may be adsorbed or attached to the conductive connectors 190, a failure in which the conductive burr 400BR electrically short-circuits two adjacent conductive connectors 190 may be reduced or suppressed because the length L of the conductive burr 400BR is smaller than the distance D2 between the conductive connectors 190.

The embodiments of the present disclosure are described herein. A person having ordinary knowledge in the art to which the present disclosure pertains will understand that the present disclosure may be implemented in a modified form without departing from an intrinsic characteristic of the present disclosure. Accordingly, the disclosed embodiments should be considered from a descriptive viewpoint, not from a limitative viewpoint. The range of the present disclosure is described in the claims not the aforementioned description, and all differences within an equivalent range thereof should be construed as being included in the present disclosure.

What is claimed is:

1. A semiconductor package comprising:
a package substrate;
a semiconductor die disposed over the package substrate;
an encapsulant layer configured to surround the semiconductor die; and
a shield layer configured to surround the encapsulant layer and to cover a side of the package substrate;
wherein the package substrate comprises:
a first dielectric layer;
a first ground trace disposed on the first dielectric layer;
connection patterns configured to connect the first ground trace and the shield layer; and
a second dielectric layer configured to surround the first ground trace and the connection patterns, wherein the second dielectric layer comprises recesses disposed in the side of the package substrate.

2. The semiconductor package of claim 1, wherein the package substrate comprises:
a first surface configured to face the semiconductor die;
a second surface configured opposite to the first surface; and
the side configured to connect the first surface and the second surface, and
wherein the recesses are spaced apart from each other and are repeatedly disposed along an edge where the second surface and side of the package substrate meet, and
wherein the second surface is a surface of the second dielectric layer.

3. The semiconductor package of claim 1, wherein the shield layer is bonded to sides of the connection patterns.

4. The semiconductor package of claim 1, further comprising conductive connectors attached to the package substrate.

5. The semiconductor package of claim 4, wherein the recesses formed in the second dielectric layer are spaced apart at a distance that is narrower than a distance between the conductive connectors.

6. The semiconductor package of claim 4, wherein:
the conductive connectors comprise solder balls, and
the second dielectric layer comprises a solder resist layer that exposes the solder balls.

7. The semiconductor package of claim 4, wherein the package substrate further comprises first signal traces that are spaced apart from the first ground trace and are connected to the conductive connectors.

8. The semiconductor package of claim 7, wherein the package substrate comprises:
a third dielectric layer disposed on the first dielectric layer;
a second ground trace disposed between the first dielectric layer and the third dielectric layer and connected to the shield layer; and
second signal traces separated from the second ground trace.

9. The semiconductor package of claim 8, wherein the second signal traces are disposed to overlap the first ground trace.

10. The semiconductor package of claim 1, wherein the shield layer exposes the recesses that cover the side of the package substrate.

11. A semiconductor package comprising:
a package substrate comprising a side that connects a first surface and a second surface and comprising recesses at edges where the second surface and the side meet;
a semiconductor die disposed over the package substrate;
an encapsulant layer configured to encapsulate the semiconductor die; and
a shield layer configured to cover the encapsulant layer and the side of the package substrate.

12. The semiconductor package of claim 11, wherein the recesses are spaced apart from each other and are repeatedly disposed along the edges of the package substrate.

13. The semiconductor package of claim 11, wherein the recesses are recessed from the side of the package substrate.

14. The semiconductor package of claim 11, further comprising conductive connectors attached to the package substrate.

15. The semiconductor package of claim 14, wherein the recesses of the package substrate are spaced apart at a distance that is narrower than a distance between the conductive connectors.

16. The semiconductor package of claim 15, wherein the package substrate comprises:
signal traces to which the conductive connectors are connected;
a ground trace separated from the signal traces; and
a plurality of connection patterns configured to connect the ground trace to the shield layer,
wherein one of the recesses is disposed between consecutive connection patterns.

17. The semiconductor package of claim 16, wherein:
the package substrate further comprises a dielectric layer configured to block the ground trace and the connection patterns by covering the ground trace and the connection patterns, and
the recesses are disposed in the dielectric layer.

18. The semiconductor package of claim 17, wherein:
the conductive connectors comprise solder balls, and
the dielectric layer comprises a solder resist layer that exposes the solder balls.

19. The semiconductor package of claim 11, wherein the shield layer covers portions of the side between the recesses.

20. The semiconductor package of claim 11, wherein the shield layer comprises an inward-outward feature.
